(19) United States
(12) Patent Application Publication
(10) Pub. No.: US 2008/0080607 A1
(43) Pub. Date: Apr. 3, 2008

(54) DYNAMIC EQUALIZER ALGORITHM IN DIGITAL COMMUNICATION EQUIPMENT FOR MULTIPATH COMPENSATION AND INTERFERENCE CANCELLATION

(76) Inventor: Punit Shah, Lawrenceville, GA (US)

Correspondence Address: ARRIS INTERNATIONAL, INC, 3871 LAKEFIELD DRIVE, SUWANEE, GA, 30024, US

(21) Appl. No.: 11/865,630

(22) Filed: Oct. 1, 2007

Related U.S. Application Data
(60) Provisional application No. 60/848,436, filed on Sep. 29, 2006.

(51) Int. Cl. H03H 7/40; H03D 1/04

(52) U.S. Cl. 375/232; 375/346

(57) ABSTRACT

A digital equalizer of a communication signal processor includes a shift register having a fixed portion and a variable portion. The fixed portion includes delay taps that are optimized for mitigating the effects of reflections of a desired signal. The variable portion includes delay taps, the configuration of which can be optimized either for mitigating the effects of reflections (reflection mode) or to suppress spurious noise (spurious mode). The decision whether to switch between a current mode and the other mode is based on statistical analysis of signal symbols received during a sample window. If statistical analysis metrics are outside predetermined criteria, an analysis portion of the processor instructs the variable portion to change modes. The digital equalizer algorithm for adjusting the variable portion can be used for initial lock. The sample window size can also be dynamically updated for use during continuous operation.

### CROSS REFERENCE TO RELATED APPLICATION

This application claims priority under 35 U.S.C. 119(e) to the benefit of the filing date of Shah, U.S. provisional patent application No. 60/848,436 entitled “Dynamic equalizer algorithm in digital communications for multipath compensation and interference cancellation,” which was filed Sep. 29, 2006, and is incorporated herein by reference.

### FIELD OF THE INVENTION

This invention relates, generally, to communication networks and, more particularly, to dynamically and automatically adjusting a digital equalizer in response to changing noise signals in a communication network environment.

### BACKGROUND

In any digital communications system, multipath delays and in channel spurs can affect the Bit Error Rate (BER) of the receiver. Equalizers are used to correct for multipath delays and spur cancellation. By monitoring the received signal quality a dynamic allocation of equalizer taps for multipath delay compensation/mitigation and spur cancellation is possible. For a given equalizer size this algorithm provides an optimal dynamic solution for receiver performance. During initial locking mechanism to the received signal, no prior knowledge of channel impairments is known. Traditional locking methods are therefore prone to multipath and interference effects and require a certain threshold of signal quality to lock. Some commercially available signal processors include variable portions that can operate to cancel spurious noise or another mode to mitigate the effects of reflections of a desired signal. There is a need for a method and system for automatically and dynamically changing the configuration of the equalizer when noise metrics of the received signal are outside of predetermined criteria.

### BRIEF DESCRIPTION OF DRAWINGS

FIG. 1 illustrates a block diagram of a digital equalizer showing multiple taps.

FIG. 2 illustrates a flow diagram of a method for adjusting a variable portion of taps based on measured signal quality parameters.

FIG. 3 illustrates a flow diagram for measuring signal parameters and adjusting a digital equalizer in response thereto based on a predetermined signal monitoring window size.

### DETAILED DESCRIPTION

As a preliminary matter, it readily will be understood by those persons skilled in the art that the present invention is susceptible of broad utility and application. Many methods, embodiments and adaptations of the present invention other than those herein described, as well as many variations, modifications, and equivalent arrangements, will be apparent from or reasonably suggested by the present invention and the following description thereof, without departing from the substance or scope of the present invention.

Accordingly, while the present invention has been described herein in detail in relation to preferred embodiments, it is to be understood that this disclosure is only illustrative and exemplary of the present invention and is made merely for the purposes of providing a full and enabling disclosure of the invention. The foregoing disclosure is not intended nor is to be construed to limit the present invention or otherwise to exclude any such other embodiments, adaptations, variations, modifications and equivalent arrangements, the present invention being limited only by the claims appended hereto and the equivalents thereof.

The described Dynamic Equalizer Algorithm (“DEA”) is applicable to use with digital communication networks, such as a fully loaded coaxial cable plant, in canceling effects of various types of noise signals, including channel spurs, white noise and micro-reflections (multipath delays). The DEA enhances performance during initial locking to the received signal where traditional locking methods do not work.

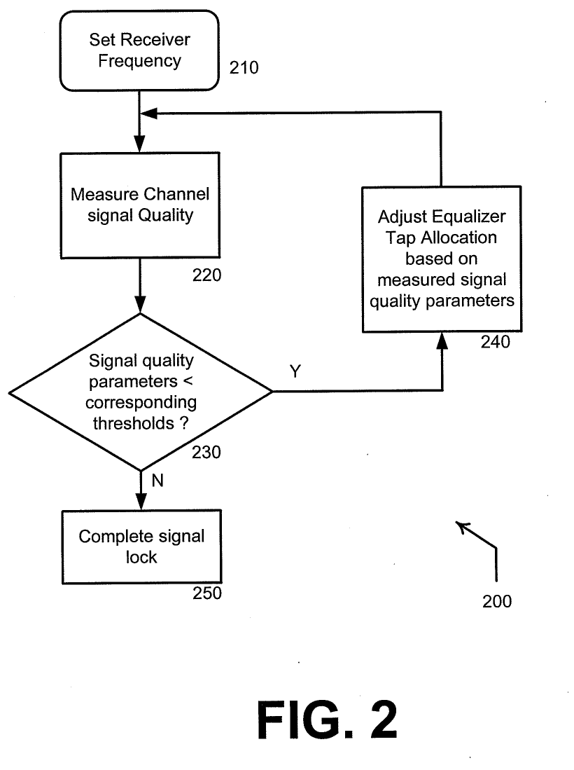

The algorithm works by assessing the channel quality (i.e. noise vs. desired signal) during the initial locking procedure and adjusts the equalizer taps accordingly, as discussed in more detail below in reference to FIG. 2. Therefore the algorithm facilitates a communication device that employs it to lock to signals with lower Signal to Noise and Interference Ratios (SNIR) than would otherwise be possible. Testing has shown the DEA to be successful with digital communications over a fully loaded coaxial cable plant having impairment caused by, for example, the following types of undesirable noise and interference:
additive white Gaussian noise (AWGN)
composite Triple Beat (CTB) spurs
Composite Second Order (CSO) beats
Micro-reflections (reflections of a desired signal)

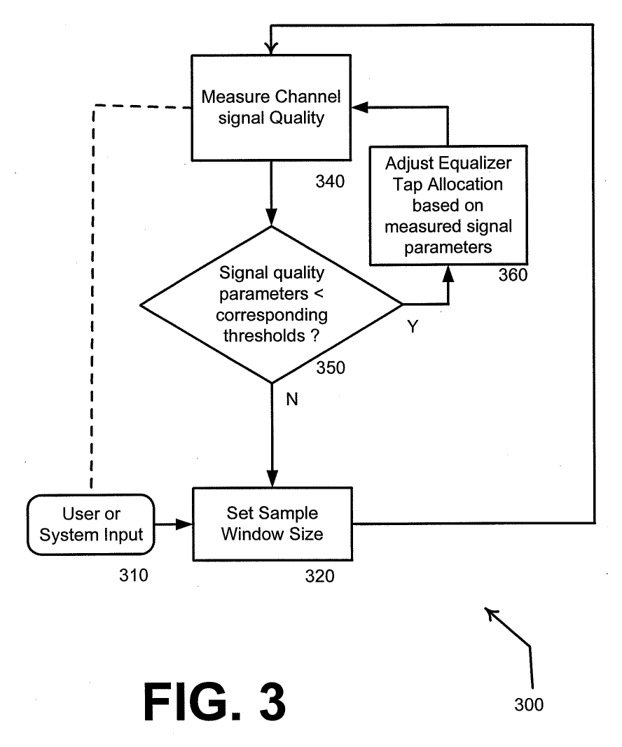

After initial lock, the equalizer tap assignments may be dynamically adjusted based on measurements of the received signal quality. As illustrated in FIG. 3, after the steps similar to those shown in FIG. 2 are performed, an additional loop of the algorithm may be implemented that allows the algorithm to continuously monitor during successive monitoring periods, or windows. A sample window size value may be selected by, for example, a user input, or an automatic system input. The value may be used in a counter that determine how long a processor acquiring and processing signal metrics acquires signal data.

As there may be multiple ways to use the taps of a digital equalizer for interference cancellation and multipath delay compensation, the algorithm is not limited to a particular implementation and should work regardless of the actual arrangement/configuration of taps. However, it will be appreciated that a goal is to cancel spurious noise signals and to enhance, if possible, a first-received desired signal with reflected versions of the same signal that are received after the first-received signal.

The Dynamic Equalizer Algorithm provides an optimal solution for digital communications systems with in-channel spurs (or interference) and multipath delays. The optimal performance is achieved by monitoring the received channel signal quality and dynamically altering the number of equalizer taps used for cancellation, of spurious signals and/or correction of multipath delays in a variable portion of the equalizer.

Signal quality monitor rate can be adjusted based on time variant channel conditions. This is achieved by changing the monitoring interval, or monitoring sample window size, of the received signal such that either the longest echo or the maximum spurious signal level in-channel is reasonably invariant over this duration. The channel invariance time can be further extended by allowing for guard windows for spurious signal and/or multipath delays that define the performance boundaries allowable for the new incoming received data.

The DEA has been successfully demonstrated to work in digital communications over coaxial cable. However, the algorithm can be used in other communication systems, such as wireless, cellular, radio, etc., and wherever digital equalizers are used. The DEA facilitates locking to a received signal during conditions where traditional methods would not. The DEA also provides flexibility that allows for varying signal quality thresholds (for example different operational requirements, previous channel statistics etc.); time between channel quality measurements/assessments can be variable (for example based on but, not limited, to previous signal statistics like Mean Square Error (MSE) BER, Code Error Rate (CER), equalizer tap values and timing offsets).

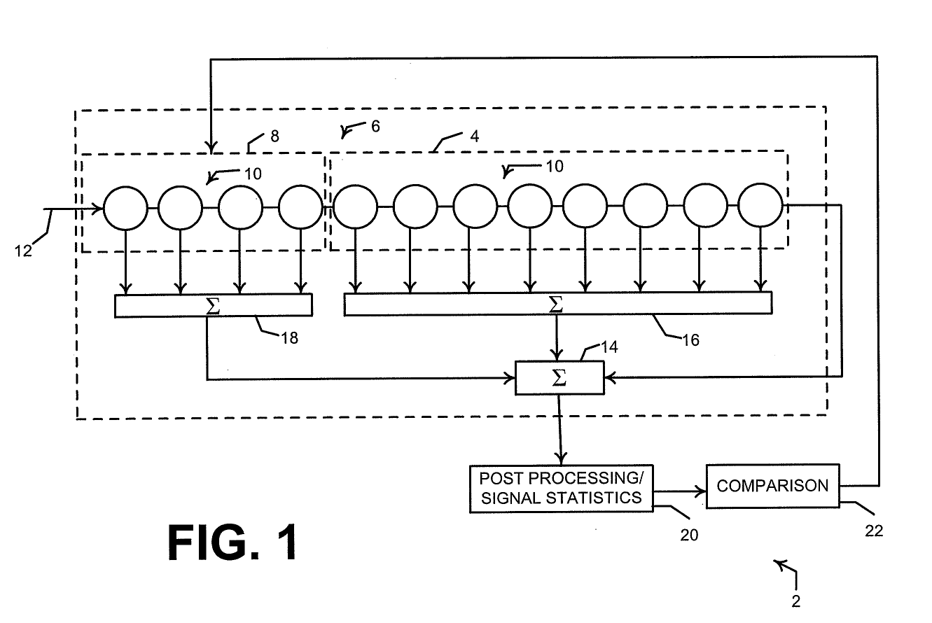

Turning now to the figures, FIG. 1 illustrates part of a digital equalizer 2 that includes fixed portion 4 of a shift register 6, and a variable portion 8 of the shift register. Each portion of shift register 6 includes a plurality of taps 10 that correspond to a predetermine amount of delay that is applied to a signal received at input 12 before being combined with the signal at final mixer 14. It will be appreciated that the predetermined amount of delay induced by each tap 10 may be based on a desired signal to be received at input 12. For example, an operator, or automatic controls, may provision equalizer 2 for a given delay time between taps 10 if the desired signal at input 12 is a quadrature amplitude modulation (“QAM”) 64 signal and another delay time if the desired signal is QAM 256.

Fixed portion mixer 16 sums the tap outputs 10 of fixed portion 4 and variable portion mixer 18 sums the tap outputs 10 of variable portion 8. Mixers 16 and 18 both feed into final mixer 14, which combines the outputs from the taps with a non-delayed version of the desired signal received at input 12.

Post processing circuitry 20 monitors the received signal at input 12 and among other functions determines whether variable portion 8 should be configured to cancel the effects of spurious noise or to mitigate the effects of micro reflections (also referred to as reflections or echo) of a desired signal, which is part of the overall signal present at input 12. It will be appreciated that a shift register such as shift register 6 may be found in commercially available devices designed for telecommunication systems. Texas Instruments, Inc. offers an example of such a device in their PUMA III brand of processors. Some cable television devices that provide data and telephony services according to the data over cable service interface specification (“DOCSIS”) and PacketCable standards, both administered by CableLabs, Inc., for example, use PUMA III processors.

The PUMA III line of processors, for example, provides a shift register that includes a fixed portion and a variable portion. The fixed portion provides optimal weighting to its taps to counteract the effects of micro reflections. However, the ideal weighting to counteract the effects of a spurious noise signal may be different than what is optimum for mitigating reflections of the desired signal. DOCSIS requires that a device be able to cancel the effects of micro reflections of up to 4.5 μS.

To cancel the negative effects of both spurious noise and reflections of desired signals, the tap weights assigned to each of taps 10 of variable portion 8 can be optimized to mitigate the effects of either reflections or spurious noise. Variable portion 8 can operate in either a ‘reflection optimized mode’ or a ‘spurious noise optimized mode’, referred to herein as ‘reflection mode’ and ‘spurious mode’ respectively.

When operating in reflection mode, portions 4 and 10 can combine together to mitigate the effects of longer reflection times than if only fixed portion 4 is used to mitigate reflections. On the other hand, if reflections are less than, for example, 3 μS, then variable portion may be set to cancel spurious noise. Post processing 20 is a simplified representation of circuitry and software that monitors the signal present at input 12 at a given time and in conjunction with comparison portion 22, instructs variable portion 8 whether to operate in reflection mode or spurious mode. Post processor 20 may evaluate a number of signal quality parameters from a signal received at input 12, processed through shift register 6 and finally mixed by mixer 14, such as, for example, mean square error, code error rate, and other values representing errors in a received signal. If post processor 20 measures signal quality statistics of the signal presented by mixer 14, and comparison by comparison portion 22 determines that a measured value for one or more of the measured parameters exceeds a predetermined threshold, then the monitor would instruct variable portion 8 to switch from its current mode to the other mode.

Thus, for example, if post processor circuitry 20 and comparison portion 22 determine that based on measured error parameters, noise is too high at input 12 while variable portion is operating in spurious mode, the post processor would instruct the variable portion to switch to reflection mode. Noise level is determined based on where the ‘plot’ of each symbol at the output of final mixer 14 falls on a corresponding constellation chart. The use of constellation charts for representing a ‘symbol’ in certain modulation schemes, such as QAM, is known in the art.

Turning now to FIG. 2, a flow diagram of a method 200 for dynamically changing a variable portion is shown. At step 210, the receiver of a communication device for receiving a communication signal is set, either manually or automatically and tuned to the set frequency. After the frequency is tuned, the signal is processed through various stages, including an equalizer stage. A monitoring stage following the output of the equalizer stage monitors the signal and measures quality parameters of the signal during a period having a current sample window size value at step 220. The quality of the signal may be determined according to how well each received symbol (in a QAM signal, for example) matches one of the ideal QAM symbols of the QAM scheme's constellation. Statistical operations are performed on the symbols of the received signal evaluating how many and how severely received symbols in a given measurement window deviate from the corresponding ideal symbols. The number of samples is selected based on the symbol rate.

The measured and assimilated statistics for the analyzed symbols at step 220 are compared to threshold value(s) for the given statistic, or statistics and a determination is made at step 230 whether the noise statistics exceed one or more of the threshold value(s). If so, a control signal is sent to the digital equalizer shown in FIG. 1 to change from the current mode of operation to the other mode (reflection mode or spurious mode) at step 240, in an attempt to mitigate the noise and/or reflection signals that may be impeding the desired signal, and thus causing the symbols to deviate from their corresponding ideal symbol placement on the constellation.

If the determination at step 230 is that the received symbols do not statistically deviate from their corresponding ideal symbols more than a predetermined amount, the device operating method 200 completes locking to the tuned signal at step 250.

In an enhancement to method 200, a flow diagram of a method 300 shown in FIG. 3 illustrates continuously operating the method described in reference to FIG. 2. Steps 340, 350 and 360 correspond to similar steps 220, 230 and 240 shown in reference to FIG. 2. Continuing with discussion of FIG. 3, a user may input a value at step 310 that determines the sample window size value (in units of time) over which samples of processed incoming signal information (e.g., symbols) are measured. The updated sample window size value input at step 310 can also be manually determined based on an algorithm that attempts to improve the results of the noise performance of the device operating method 300. Thus, a dashed line shows that the processing circuitry that monitors, determines, measures and calculates the noise statistics at step 340 can also determine that the size of the sample window over which time samples of a processed signal are taken.

At step 320, either the user inputted value or the automatically determined sample window size value replaces the sample current window size value at step 320 and method 300 returns to step 340. It will be appreciated that before step 320 executes, a check is made to determine whether an updated sample window size value is available, from either manual or automatic calculation, to replace the current sample window size value. At step 340, the measuring and sampling portion 20 shown in FIG. 1 acquires data samples from the processed signal and the decision whether the statistics exceed predetermine threshold is made by comparison portion 22 at step 350 shown in FIG. 3.

The method and system described above has been tested and successful operation confirmed in a cable data system. However, the aspects described herein can also be used in many other communication systems, including, but not limited to, wireless digital communication systems, optical communication systems, digital communications over wire (for example but not limited to DSL modems), and many others. Similar techniques could also be adapted for use in audio applications.

What is claimed is:

1. A method for improving locking of a communication device to a signal on a communication channel comprising:
receiving the signal at the communication device;
evaluating predetermined parameters of signal quality of the received signal to obtain measured values for the parameters; and
adjusting tap allocation of a digital equalizer based on the measured values.

2. The method of claim 1 further comprising attempting to lock the communication device to the signal.

3. The method of claim 1 further comprising:
during operation of a communication device replacing a current sample window size with a new sample window size if an updated sample window size value is available.

4. The method of claim 1 wherein the step of adjusting tap allocation of the digital equalizer based on the measured values includes adjusting the number of cells in a shift register of the digital equalizer.

5. The method of claim 1 where in the step of adjusting tap allocation of the digital equalizer based on measured values includes changing a portion of a variable portion of a shift register of the digital equalizer from a current configuration to another configuration, wherein the variable portion is variable with respect to being optimized for mitigating the effects of either spurious noise or reflections of a desired signal.

6. The method of claim 5 wherein the current configuration is a reflection mode and the other configuration is a spurious mode.

7. The method of claim 5 wherein the current configuration is a spurious mode and the other configuration is a reflection mode.

8. The method of claim 3 wherein the current sample window size value is ten seconds.

9. A system for improving locking of a communication device to a signal on a communication channel, comprising:
tuning circuitry for receiving the signal at the communication device;
processor for evaluating predetermined parameters of signal quality of the received signal to obtain measured values for the parameters and for comparing the measured value with predetermined threshold values;
a shift register composing a digital equalizer, wherein the shift register has a fixed portion of a first predetermined number of taps and a variable portion with a second predetermined number of taps; and
control circuitry for instructing the variable portion to switch from a first mode of operation to a second mode of operation based a comparison of the measured values to the predetermined values made by the processor.

10. The system of claim 9 wherein the first predetermined number of taps of the fixed portion includes sixteen taps.

11. The system of claim 9 wherein the second predetermined number of taps of the variable portion includes eight taps.

12. The system of claim 9 wherein the first mode of operation is a reflection mode.

13. The system of claim 9 wherein the first mode of operation is a spurious mode.

14. A method for mitigating signal impairment of a communication device in a communication system, comprising;
receiving a communication signal at the communication device;
measuring values of predetermine quality parameters of the signal for a predetermined period having a predetermined sample window value;
performing statistical analysis of the measured values to obtain signal quality metrics:
evaluating the signal quality metrics against predetermined corresponding thresholds to determine whether to change a variable portion of a sift register of a digital equalizer from a current mode to another mode; and
adjusting tap allocation of a digital equalizer based on the evaluation of the signal quality metrics.

15. The method of claim 14 further comprising continuing to measure the values of the received signal for the predetermine sample window value.

16. The method of claim 14 further comprising continuing to measure the values of the received signal for an available updated sample window value.

17. The method of claim 16 wherein the updated sample window value is manually input.

18. The method of claim 16 wherein the updated sample window value is automatically determined based on the signal quality metrics.
